(19) United States
(12) Patent Application Publication
(10) Pub. No.: US 2022/0293484 A1
(43) Pub. Date: Sep. 15, 2022

(54) INTEGRATED CIRCUIT PACKAGE SYSTEM

(71) Applicant: Aptos Technology Inc., Miaoli County (TW)

(72) Inventors: Chun-Lung HUANG, HsinChu City (TW); Chih-Ming CHEN, Taoyuan City (TW)

(21) Appl. No.: 17/683,663

(22) Filed: Mar. 1, 2022

(30) Foreign Application Priority Data
Mar. 15, 2021 (TW) 110109062

(51) Int. Cl. H01L 23/367; H01L 25/065

(52) U.S. Cl. CPC H01L 23/3672; H01L 25/0655; H01L 23/3735

(57) ABSTRACT

An integrated circuit package system includes a substrate, a plurality of leads, N semiconductor devices, N first heat sinks, an encapsulating body, a second heat sink and a plurality of heat-dissipating fins protruding upward from the second heat sink, where N is a natural number. The leads are formed on a lower surface of the substrate. Each of the semiconductor devices is attached on an upper surface of the substrate, and includes a plurality of bonding pads which each is electrically connected to the corresponding lead. Each first heat sink is thermally coupled to a first top surface of the corresponding semiconductor device. The encapsulating body is formed to cover the substrate, the N semiconductor devices and the N first heat sinks such that the leads are exposed. The second heat sink is mounted on the encapsulating body, and is thermally coupled to the N first heat sinks.

### CROSS-REFERENCE TO RELATED APPLICATION

This utility application claims priority to Taiwan Application Serial Number 110109062, filed Mar. 15, 2021, which is incorporated herein by reference.

### BACKGROUND OF THE INVENTION

### 1. Field of the Invention

The invention relates to an integrated circuit package system, and in particular, to an integrated circuit package system with high heat dissipation performance.

### 2. Description of the Prior Art

Most of the traditional semiconductor power devices are packaged with a Quad Flat No leads (QFN) structure. Traditional QFN package structure s use a substrate or a lead frame to provide leads and to serve as a pedestal for the package. Whether it is a traditional QFN package structure using a substrate or a lead frame, most of the heat sinks are bonded to the lower surface of the substrate or the lower surface of the land of the lead frame. Thereby, the heat generated by the semiconductor power device during operation is conducted to the heat sink through the substrate or the land of the lead frame, and then is dissipated by the heat sink. That is to say, in the traditional QFN package structure, the heat dissipation channel is established between the semiconductor power device, the substrate or the land of the lead frame and the heat sink.

However, with the development of semiconductor power devices in the direction of increasing power, the heat dissipation performance of the traditional QFN packaging structure has not met the requirements.

In addition, a System in a Package (SiP) currently on the market directly packages several semiconductor chips or dies with different functions into a single integrated circuit with complete functions. The SiP can also use the QFN package structure. However, the SiP using the QFN package structure also encounters the problem that the heat dissipation performance must be improved.

In addition, the thermal coupling between the heat dissipation device and the semiconductor device of the integrated circuit package system using the QFN package structure also needs to be improved, so as to improve the overall heat dissipation performance.

### SUMMARY OF THE INVENTION

Accordingly, one scope of the invention is to provide an integrated circuit packaging system based on a QFN package structure and having high heat dissipation performance. The integrated circuit package system according to the invention can be applied to the package of semiconductor power devices, and can also be applied to SiP.

An integrated circuit package system according to a first preferred embodiment of the invention includes a substrate, a plurality of via hole plugs, a plurality of leads, N semiconductor devices, a plurality of metal wires, N first thermal interface material layers, N first metal layers, N first heat sinks, N second metal layers, an encapsulating body, N second thermal interface material layers, a second heat sink, and a plurality of heat-dissipating fins, where N is a natural number. The substrate has an upper surface and a lower surface. The plurality of via hole plugs are formed on the substrate, and penetrate from the upper surface to the lower surface of the substrate. The plurality of leads are formed on the lower surface of the substrate. Each lead corresponds to one of the via hole plugs, and is bonded to the corresponding via hole plug. Each semiconductor device is via a respective bottom surface attached on the upper surface of the substrate. Each semiconductor device includes a plurality of bonding pads formed on a respective first top surface of said one semiconductor device. Each metal wire corresponds to one of the via hole plugs and one of the bonding pads Each metal wire is bonded to the corresponding via hole plug and the corresponding bonding pad. Each first thermal interface material layer corresponds to one of the N semiconductor devices, and is coated on the first top surface of the corresponding semiconductor device. Each first metal layer corresponds to one of the N first thermal interface material layers, and is formed on the corresponding first thermal interface material layer. Each first heat sink corresponds to one of the N first metal layers, and is bonded onto the corresponding first metal layer. Each second metal layer corresponds to one of the N first heat sinks, and is formed on the corresponding first heat sink. The encapsulating body is formed of an encapsulating material to cover the substrate, the N semiconductor devices, the metal wires, the N first thermal interface material layers, the N first metal layers and the N first heat sinks such that the plurality of leads and the N second metal layers are exposed. Each second thermal interface material layer corresponds to one of the N second metal layers, and is coated on the corresponding second metal layer. The second heat sink is mounted on a second top surface of the encapsulating body, and is bonded to the N second thermal interface material layers. The plurality of heat-dissipating fins protrude upward from the second heat sink.

An integrated circuit package system according to a second preferred embodiment of the invention includes a lead frame, N semiconductor devices, a plurality of metal wires, N first thermal interface material layers, N first metal layers, N first heat sinks, N second metal layers, an encapsulating body, N second thermal interface material layers, a second heat sink, and a plurality of heat-dissipating fins, where N is a natural number. The lead frame includes a land and a plurality of leads. Each semiconductor device is via a respective bottom surface attached on the land. Each semiconductor device includes a plurality of bonding pads formed on a respective first top surface of said one semiconductor device. Each metal wire corresponds to one of the leads and one of the bonding pads. Each metal wire is bonded to the corresponding lead and the corresponding bonding pad. Each first thermal interface material layer corresponds to one of the N semiconductor devices, and is coated on the first top surface of the corresponding semiconductor device. Each first metal layer corresponds to one of the N first thermal interface material layers, and is formed on the corresponding first thermal interface material layer. Each first heat sink corresponds to one of the N first metal layers, and is bonded onto the corresponding first metal layer. Each second metal layer corresponds to one of the N first heat sinks, and is formed on the corresponding first heat sink. The encapsulating body is formed of an encapsulating material to cover the lead frame, the N semiconductor devices, the metal wires, the N first thermal interface material layers, the N first metal layers and the N first heat sinks such that the plurality of leads and the N second metal layers are exposed. Each second thermal interface material layer corresponds to one of the N second metal layers, and is coated on the corresponding second metal layer. The second heat sink is mounted on a second top surface of the encapsulating body, and is bonded to the N second thermal interface material layers. The plurality of heat-dissipating fins protrude upward from the second heat sink.

An integrated circuit package system according to a third preferred embodiment of the invention includes a substrate, a plurality of via hole plugs, a plurality of leads, N semiconductor devices, a plurality of bumps, N first thermal interface material layers, N first metal layers, N first heat sinks, N second metal layers, an encapsulating body, N second thermal interface material layers, a second heat sink, and a plurality of heat-dissipating fins, where N is a natural number. The substrate has an upper surface and a lower surface. The plurality of via hole plugs are formed on the substrate, and penetrate from the upper surface to the lower surface of the substrate. The plurality of leads are formed on the lower surface of the substrate. Each lead corresponds to one of the via hole plugs, and is bonded to the corresponding via hole plug. Each semiconductor device has a respective first top surface and a respective bottom surface, and includes a plurality of bonding pads formed on the bottom surface of said one semiconductor device. Each bump corresponds to one of the via hole plugs and one of the bonding pads. Each bump is bonded to the corresponding via hole plug and the corresponding bonding pad. Each first thermal interface material layer corresponds to one of the N semiconductor devices, and is coated on the first top surface of the corresponding semiconductor device. Each first metal layer corresponds to one of the N first thermal interface material layers, and is formed on the corresponding first thermal interface material layer. Each first heat sink corresponds to one of the N first metal layers, and is bonded onto the corresponding first metal layer. Each first heat sink has a respective second top surface. Each second metal layer corresponds to one of the N first heat sinks, and is formed on the corresponding first heat sink. The encapsulating body is formed of an encapsulating material to cover the substrate, the N semiconductor devices, the bumps, the N first thermal interface material layers, the N first metal layers and the N first heat sinks such that the plurality of leads and the N second metal layers are exposed. Each second thermal interface material layer corresponds to one of the N second metal layers, and is coated on the corresponding second metal layer. The second heat sink is mounted on a second top surface of the encapsulating body, and is bonded to the N second thermal interface material layers. The plurality of heat-dissipating fins protrude upward from the second heat sink.

An integrated circuit package system according to a fourth preferred embodiment of the invention includes a substrate, a plurality of via hole plugs, a plurality of leads, N semiconductor devices, a plurality of bumps, N first thermal interface material layers, N first metal layers, a first heat sink, a second metal layer, an encapsulating body, a second thermal interface material layer, a second heat sink, and a plurality of heat-dissipating fins, where N is a natural number. The substrate has an upper surface and a lower surface. The plurality of via hole plugs are formed on the substrate, and penetrate from the upper surface to the lower surface of the substrate. The plurality of leads are formed on the lower surface of the substrate. Each lead corresponds to one of the via hole plugs, and is bonded to the corresponding via hole plug. Each semiconductor device has a respective first top surface and a respective bottom surface, and includes a plurality of bonding pads formed on the bottom surface of said one semiconductor device. The N first top surfaces of the N semiconductor devices are coplanar. Each bump corresponds to one of the via hole plugs and one of the bonding pads. Each bump is bonded to the corresponding via hole plug and the corresponding bonding pad. Each first thermal interface material layer corresponds to one of the N semiconductor devices, and is coated on the first top surface of the corresponding semiconductor device. Each first metal layer corresponds to one of the N first thermal interface material layers, and is formed on the corresponding first thermal interface material layer. The first heat sink is bonded onto the N first metal layers. The second metal layer is formed on the first heat sink. The encapsulating body is formed of an encapsulating material to cover the substrate, the N semiconductor devices, the bumps, the N first thermal interface material layers, the N first metal layers and the first heat sink such that the plurality of leads and the second metal layer are exposed. The second thermal interface material layer is coated on the second metal layer. The second heat sink is mounted on a second top surface of the encapsulating body, and is bonded to the second thermal interface material layer. The plurality of heat-dissipating fins protrude upward from the second heat sink.

In one embodiment, the N semiconductor devices can include a semiconductor chip or a semiconductor die.

Distinguish from the prior art, the integrated circuit package system according to the invention does not bond the heat sink on the lower surface of the substrate or the lower surface of the land of the lead frame, but thermally couples the first heat sinks and the second heat sinks to the top surface of the semiconductor devices, improves the thermal coupling between the first heat sinks, the second heat sinks and the semiconductor devices, and effectively dissipates the heat generated by the semiconductor devices during operation the plurality of heat-dissipating fins through the first heat sinks and the second heat sinks. Thereby, the integrated circuit package system according to the invention has high heat dissipation performance.

The advantage and spirit of the invention may be understood by the following recitations together with the appended drawings.

### BRIEF DESCRIPTION OF THE APPENDED DRAWINGS

FIG. 1 is a perspective view of an integrated circuit package system according to the first preferred embodiment of the invention.

FIG. 2 is a cross-sectional view of the integrated circuit package system according to the first preferred embodiment of the invention in FIG. 1 along the line A-A.

FIG. 3 is a cross-sectional view of the integrated circuit package system according to the second preferred embodiment of the invention.

FIG. 4 is a cross-sectional view of the integrated circuit package system according to the third preferred embodiment of the invention.

FIG. 5 is a cross-sectional view of the integrated circuit package system according to the fourth preferred embodiment of the invention.

### DETAILED DESCRIPTION OF THE INVENTION

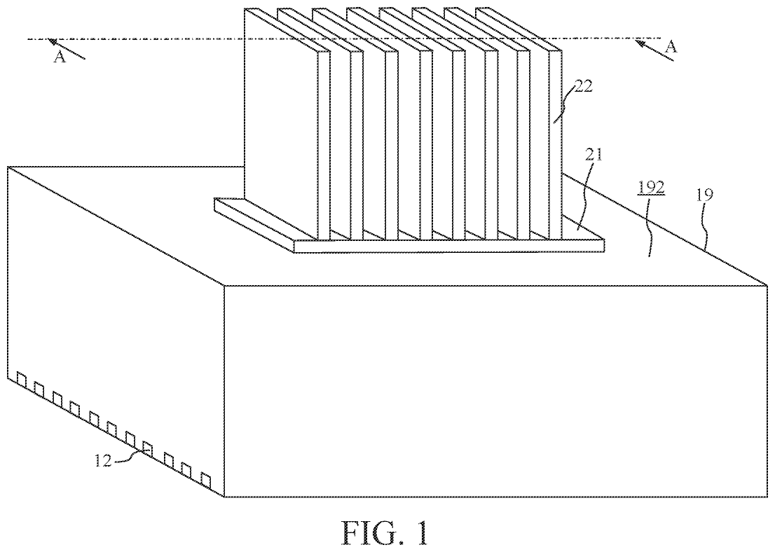

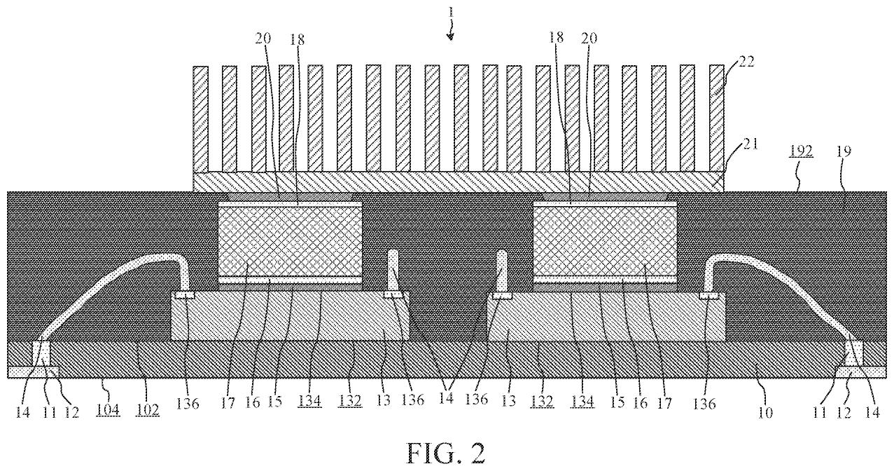

Referring to FIG. 1 and FIG. 2, those drawings schematically illustrate an integrated circuit package system 1 according to the first preferred embodiment of the invention. FIG. 1 schematically illustrates with a perspective view the integrated circuit package system 1 according to the first preferred embodiment of the invention. FIG. 2 is a cross-sectional view of the integrated circuit package system 1 in FIG. 1 along the line A-A. The integrated circuit package system 1 according to the first preferred embodiment of the invention can be applied to the package of semiconductor power devices, and can also be applied to SiP.

As shown in FIG. 1 and FIG. 2, the integrated circuit package system 1 according to the first preferred embodiment of the invention includes a substrate 10, a plurality of via hole plugs 11, a plurality of leads 12, N semiconductor devices 13, a plurality of metal wires 14, N first thermal interface material layers 15, N first metal layers 16, N first heat sinks 17, N second metal layers 18, an encapsulating body 19, N second thermal interface material layers 20, a second heat sink 21, and a plurality of heat-dissipating fins 22, where N is a natural number. In FIG. 2, only two semiconductor devices 13 are illustrated as a representative.

The substrate 10 has an upper surface 102 and a lower surface 104.

The plurality of via hole plugs 11 are formed on the substrate 10, and penetrate from the upper surface 102 to the lower surface 104 of the substrate 10.

The plurality of leads 12 are formed on the lower surface 104 of the substrate 10. Each lead 12 corresponds to one of the via hole plugs 11, and is bonded to the corresponding via hole plug 11.

Each semiconductor device 13 is via a respective bottom surface 132 attached on the upper surface 102 of the substrate 10. Each semiconductor device 13 includes a plurality of bonding pads 136 formed on a respective first top surface 134 of said one semiconductor device 13.

In one embodiment, the N semiconductor devices 13 can include a semiconductor chip or a semiconductor die. The semiconductor chip can be a semiconductor power device. The semiconductor die can be a semiconductor power die.

Each metal wire 14 corresponds to one of the via hole plugs 11 and one of the bonding pads 136 Each metal wire 14 is bonded to the corresponding via hole plug 11 and the corresponding bonding pad 136. In FIG. 2, the metal wires 14 that are not bonded to the via hole plugs 11 are actually bonded to the rear via hole plugs 11, so the bonding mentioned above cannot be shown in the cross-sectional view shown in FIG. 2.

Each first thermal interface material layer 15 corresponds to one of the N semiconductor devices 13, and is coated on the first top surface 134 of the corresponding semiconductor device 13.

In one embodiment, the first thermal interface material layers 15 can be, but not limited thereto, formed by curing a thermal adhesive.

Each first metal layer 16 corresponds to one of the N first thermal interface material layers 15, and is formed on the corresponding first thermal interface material layer 15.

Each first heat sink 17 corresponds to one of the N first metal layers 16, and is bonded onto the corresponding first metal layer 16.

In one embodiment, the first heat sinks 17 can be formed of SiO₂, Si₃N₄, TiO₂, SiC, Al₂O₃, AlN, BN, graphite, or the like.

Each second metal layer 18 corresponds to one of the N first heat sinks 17, and is formed on the corresponding first heat sink 17.

In one embodiment, the first metal layer 16 and the second metal layer 18 can be deposited on the corresponding first heat sink 17 in advance, but the invention is not limited thereto.

The first metal layer 16 and the second metal layer 18 formed on the first heat sink 17 in advance can fill the defects on the surface of the first heat sink 17, so as to improve the interface heat conduction performance of the first heat sink 17.

The encapsulating body 19 is formed of an encapsulating material to cover the substrate 10, the N semiconductor devices 13, the metal wires 14, the N first thermal interface material layers 15, the N first metal layers 16 and the N first heat sinks 17 such that the plurality of leads 12 and the N second metal layers 18 are exposed.

In one embodiment, the encapsulating body 19 can be formed by molding and curing of an epoxy-based resin, but the invention is not limited thereto.

Each second thermal interface material layer 20 corresponds to one of the N second metal layers 18, and is coated on the corresponding second metal layer 18.

In one embodiment, the second thermal interface material layers 20 can be, but not limited thereto, formed by curing a thermal adhesive.

The second heat sink 21 is mounted on a second top surface 192 of the encapsulating body 19, and is bonded to the N second thermal interface material layers 20. The plurality of heat-dissipating fins 22 protrude upward from the second heat sink 21.

In one embodiment, the plurality of heat-dissipating fins 22 and the second heat sink 21 can be integrally formed. The plurality of heat-dissipating fins 22 and the second heat sink 21 can be made of a metal (e.g., copper, aluminum, etc.) or a ceramic (e.g., Al₂O₃, AlN, etc.).

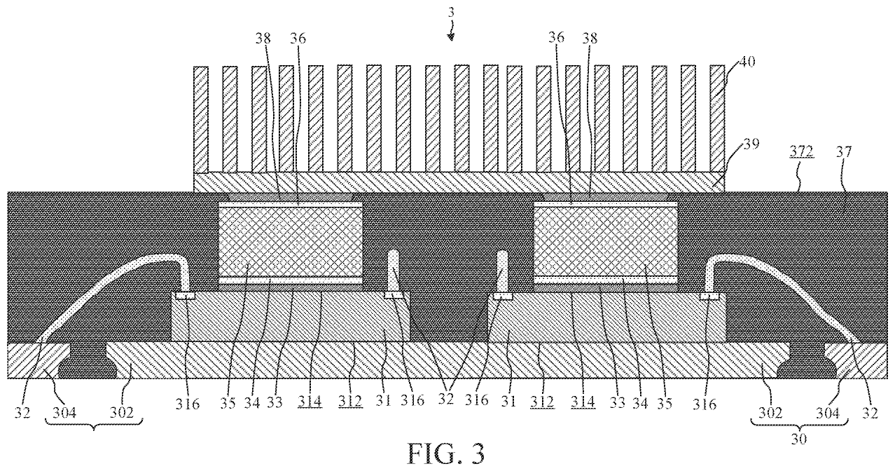

Referring to FIG. 3, FIG. 3 is a cross-sectional view of the integrated circuit package system 3 according to the second preferred embodiment of the invention. The integrated circuit package system 3 according to the second preferred embodiment of the invention can be applied to the package of semiconductor power devices, and can also be applied to SiP.

As shown in FIG. 3, the integrated circuit package system 3 according to the second preferred embodiment of the invention includes a lead frame 30, N semiconductor devices 31, a plurality of metal wires 32, N first thermal interface material layers 33, N first metal layers 34, N first heat sinks 35, N second metal layers 36, an encapsulating body 37, N second thermal interface material layers 38, a second heat sink 39, and a plurality of heat-dissipating fins 40, where N is a natural number. In FIG. 3, only two semiconductor devices 31 are illustrated as a representative.

The lead frame 30 includes a land 302 and a plurality of leads 304.

Each semiconductor device 31 is via a respective bottom surface 312 attached on the land 302 of the lead frame 30. Each semiconductor device 31 includes a plurality of bonding pads 316 formed on a respective first top surface 314 of said one semiconductor device 31.

In one embodiment, the N semiconductor devices 31 can include a semiconductor chip or a semiconductor die. The semiconductor chip can be a semiconductor power device. The semiconductor die can be a semiconductor power die.

Each metal wire 32 corresponds to one of the leads 304 and one of the bonding pads 316. Each metal wire 32 is bonded to the corresponding lead 304 and the corresponding bonding pad 316. In FIG. 3, the metal wires 32 that are not bonded to the leads 304 are actually bonded to the rear leads 304, so the bonding mentioned above cannot be shown in the cross-sectional view shown in FIG. 3.

Each first thermal interface material layer 33 corresponds to one of the N semiconductor devices 31, and is coated on the first top surface 314 of the corresponding semiconductor device 31.

In one embodiment, the first thermal interface material layers 33 can be, but not limited thereto, formed by curing a thermal adhesive.

Each first metal layer 34 corresponds to one of the N first thermal interface material layers 33, and is formed on the corresponding first thermal interface material layer 33.

Each first heat sink 35 corresponds to one of the N first metal layers 34, and is bonded onto the corresponding first metal layer 34.

In one embodiment, the first heat sinks 35 can be formed of SiO₂, Si₃N₄, TiO₂, SiC, Al₂O₃, AlN, BN, graphite, or the like.

Each second metal layer 36 corresponds to one of the N first heat sinks 35, and is formed on the corresponding first heat sink 35.

In one embodiment, the first metal layer 34 and the second metal layer 36 can be deposited on the corresponding first heat sink 35 in advance, but the invention is not limited thereto.

The first metal layer 34 and the second metal layer 36 formed on the first heat sink 35 in advance can fill the defects on the surface of the first heat sink 35, so as to improve the interface heat conduction performance of the first heat sink 35.

The encapsulating body 37 is formed of an encapsulating material to cover the lead frame 30, the N semiconductor devices 31, the metal wires 32, the N first thermal interface material layers 33, the N first metal layers 34 and the N first heat sinks 35 such that the plurality of leads 304 and the N second metal layers 36 are exposed.

In one embodiment, the encapsulating body 37 can be formed by molding and curing of an epoxy-based resin, but the invention is not limited thereto.

Each second thermal interface material layer 38 corresponds to one of the N second metal layers 36, and is coated on the corresponding second metal layer 36.

In one embodiment, the second thermal interface material layers 38 can be, but not limited thereto, formed by curing a thermal adhesive.

The second heat sink 39 is mounted on a second top surface 372 of the encapsulating body 37, and is bonded to the N second thermal interface material layers 38. The plurality of heat-dissipating fins 40 protrude upward from the second heat sink 39.

In one embodiment, the plurality of heat-dissipating fins 40 and the second heat sink 39 can be integrally formed. The plurality of heat-dissipating fins 40 and the second heat sink 39 can be made of a metal (e.g., copper, aluminum, etc.) or a ceramic (e.g., Al₂O₃, AlN, etc.).

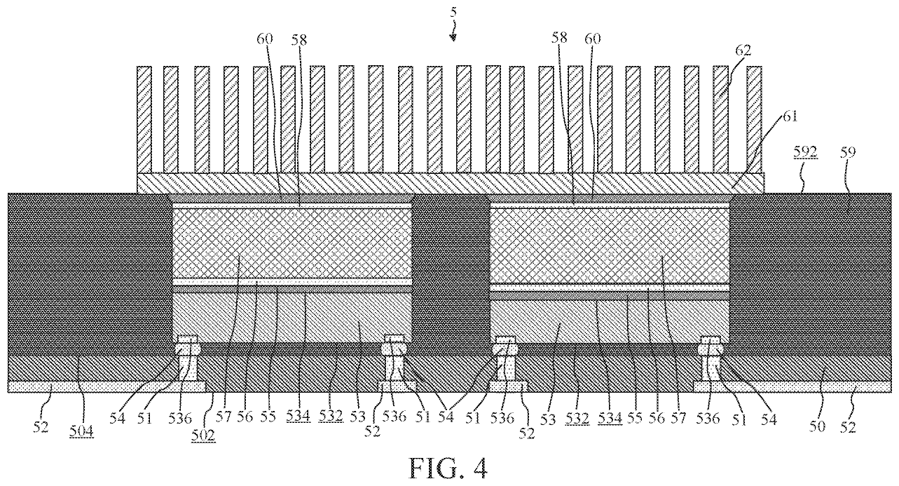

Referring to FIG. 4, FIG. 4 is a cross-sectional view of the integrated circuit package system 5 according to the third preferred embodiment of the invention. The integrated circuit package system 5 according to the third preferred embodiment of the invention can be applied to the package of semiconductor power devices, and can also be applied to SiP.

As shown in FIG. 4, the integrated circuit package system 5 according to the third preferred embodiment of the invention includes a substrate 50, a plurality of via hole plugs 51, a plurality of leads 52, N semiconductor devices 53, a plurality of bumps 54, N first thermal interface material layers 55, N first metal layers 56, N first heat sinks 57, N second metal layers 58, an encapsulating body 59, N second thermal interface material layers 60, a second heat sink 61, and a plurality of heat-dissipating fins 62, where N is a natural number. In FIG. 4, only two semiconductor devices 53 are illustrated as a representative.

The substrate 50 has an upper surface 502 and a lower surface 504.

The plurality of via hole plugs 51 are formed on the substrate 50, and penetrate from the upper surface 502 to the lower surface 504 of the substrate 50.

The plurality of leads 52 are formed on the lower surface 504 of the substrate 50. Each lead 52 corresponds to one of the via hole plugs 51, and is bonded to the corresponding via hole plug 51.

Each semiconductor device 53 has a respective first top surface 534 and a respective bottom surface 532, and includes a plurality of bonding pads 536 formed on the bottom surface 532 of said one semiconductor device 53.

In one embodiment, the N semiconductor devices 53 can include a semiconductor chip or a semiconductor die. The semiconductor chip can be a semiconductor power device. The semiconductor die can be a semiconductor power die.

Each bump 54 corresponds to one of the via hole plugs 51 and one of the bonding pads 536. Each bump 54 is bonded to the corresponding via hole plug 51 and the corresponding bonding pad 536.

Each first thermal interface material layer 55 corresponds to one of the N semiconductor devices 53, and is coated on the first top surface 534 of the corresponding semiconductor device 53.

In one embodiment, the first thermal interface material layers 55 can be, but not limited thereto, formed by curing a thermal adhesive.

Each first metal layer 56 corresponds to one of the N first thermal interface material layers 55, and is formed on the corresponding first thermal interface material layer 55.

Each first heat sink 57 corresponds to one of the N first metal layers 56, and is bonded onto the corresponding first metal layer 56. Each first heat sink 57 has a respective second top surface 572.

In one embodiment, the first heat sinks 57 can be formed of SiO₂, Si₃N₄, TiO₂, SiC, Al₂O₃, AlN, BN, graphite, or the like.

Each second metal layer 58 corresponds to one of the N first heat sinks 57, and is formed on the second top surface 572 of the corresponding first heat sink 57.

In one embodiment, the first metal layer 56 and the second metal layer 58 can be deposited on the corresponding first heat sink 57 in advance, but the invention is not limited thereto.

The first metal layer 56 and the second metal layer 58 formed on the first heat sink 57 in advance can fill the defects on the surface of the first heat sink 57, so as to improve the interface heat conduction performance of the first heat sink 57.

The encapsulating body 59 is formed of an encapsulating material to cover the substrate 50, the N semiconductor devices 53, the bumps 54, the N first thermal interface material layers 55, the N first metal layers 56 and the N first heat sinks 57 such that the plurality of leads 52 and the N second metal layers 58 are exposed.

In one embodiment, the encapsulating body 59 can be formed by molding and curing of an epoxy-based resin, but the invention is not limited thereto.

Each second thermal interface material layer 60 corresponds to one of the N second metal layers 58, and is coated on the corresponding second metal layer 58.

In one embodiment, the second thermal interface material layers 60 can be, but not limited thereto, formed by curing a thermal adhesive.

The second heat sink 61 is mounted on a second top surface 592 of the encapsulating body 59, and is bonded to the N second thermal interface material layers 60. The plurality of heat-dissipating fins 62 protrude upward from the second heat sink 61.

In one embodiment, the plurality of heat-dissipating fins 62 and the second heat sink 61 can be integrally formed. The plurality of heat-dissipating fins 62 and the second heat sink 61 can be made of a metal (e.g., copper, aluminum, etc.) or a ceramic (e.g., Al₂O₃, AlN, etc.).

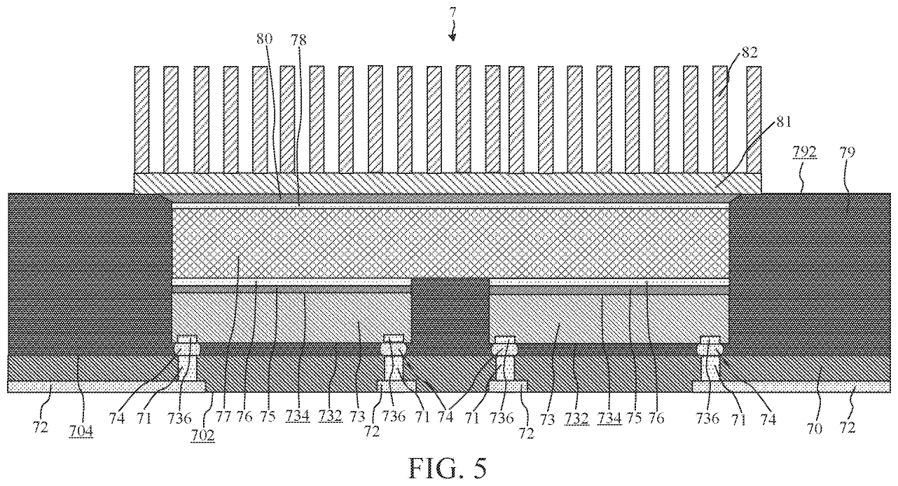

Referring to FIG. 5, FIG. 5 is a cross-sectional view of the integrated circuit package system 7 according to the fourth preferred embodiment of the invention. The integrated circuit package system 7 according to the fourth preferred embodiment of the invention can be applied to the package of semiconductor power devices, and can also be applied to SiP.

As shown in FIG. 5, the integrated circuit package system 7 according to the fourth preferred embodiment of the invention includes a substrate 70, a plurality of via hole plugs 71, a plurality of leads 72, N semiconductor devices 73, a plurality of bumps 74, N first thermal interface material layers 75, N first metal layers 76, a first heat sink 77, a second metal layer 78, an encapsulating body 79, a second thermal interface material layer 80, a second heat sink 81, and a plurality of heat-dissipating fins 82, where N is a natural number. In FIG. 5, only two semiconductor devices 73 are illustrated as a representative.

The substrate 70 has an upper surface 702 and a lower surface 704.

The plurality of via hole plugs 71 are formed on the substrate 70, and penetrate from the upper surface 702 to the lower surface 704 of the substrate 70.

The plurality of leads 72 are formed on the lower surface 704 of the substrate 70. Each lead 72 corresponds to one of the via hole plugs 71, and is bonded to the corresponding via hole plug 71.

Each semiconductor device 73 has a respective first top surface 734 and a respective bottom surface 732, and includes a plurality of bonding pads 736 formed on the bottom surface 732 of said one semiconductor device 73. In particular, the N first top surfaces 734 of the N semiconductor devices 73 are coplanar.

In one embodiment, the N semiconductor devices 73 can include a semiconductor chip or a semiconductor die. The semiconductor chip can be a semiconductor power device. The semiconductor die can be a semiconductor power die.

Each bump 74 corresponds to one of the via hole plugs 71 and one of the bonding pads 736. Each bump 74 is bonded to the corresponding via hole plug 71 and the corresponding bonding pad 736.

Each first thermal interface material layer 75 corresponds to one of the N semiconductor devices 73, and is coated on the first top surface 734 of the corresponding semiconductor device 73.

In one embodiment, the first thermal interface material layers 75 can be, but not limited thereto, formed by curing a thermal adhesive.

Each first metal layer 76 corresponds to one of the N first thermal interface material layers 75, and is formed on the corresponding first thermal interface material layer 75.

The first heat sink 77 is bonded onto the N first metal layers 76. The second metal layer 78 is formed on the first heat sink 77.

In one embodiment, the first heat sink 77 can be formed of SiO₂, Si₃N₄, TiO₂, SiC, Al₂O₃, AlN, BN, graphite, or the like.

In one embodiment, the first metal layers 76 and the second metal layer 18 can be deposited on the first heat sink 77 in advance, but the invention is not limited thereto.

The first metal layers 76 and the second metal layer 78 formed on the first heat sink 77 in advance can fill the defects on the surface of the first heat sink 77, so as to improve the interface heat conduction performance of the first heat sink 77.

The encapsulating body 79 is formed of an encapsulating material to cover the substrate 70, the N semiconductor devices 73, the bumps 74, the N first thermal interface material layers 75, the N first metal layers 76 and the first heat sink 77 such that the plurality of leads 72 and the second metal layer 78 are exposed.

In one embodiment, the encapsulating body 79 can be formed by molding and curing of an epoxy-based resin, but the invention is not limited thereto.

The second thermal interface material layer 80 is coated on the second metal layer 78.

In one embodiment, the second thermal interface material layer 80 can be, but not limited thereto, formed by curing a thermal adhesive.

The second heat sink 81 is mounted on a second top surface 792 of the encapsulating body 79, and is bonded to the second thermal interface material layer 80. The plurality of heat-dissipating fins 82 protrude upward from the second heat sink 81.

In one embodiment, the plurality of heat-dissipating fins 82 and the second heat sink 81 can be integrally formed. The plurality of heat-dissipating fins 82 and the second heat sink 81 can be made of a metal (e.g., copper, aluminum, etc.) or a ceramic (e.g., Al₂O₃, AlN, etc.).

With the detailed description of the above preferred embodiments of the invention, it is clear to understand that the integrated circuit package system according to the invention does not bond the heat sink on the lower surface of the substrate or the lower surface of the land of the lead frame, but thermally couples the first heat sinks and the second heat sinks to the top surface of the semiconductor devices, improves the thermal coupling between the first heat sinks, the second heat sinks and the semiconductor devices, and effectively dissipates the heat generated by the semiconductor devices during operation the plurality of heat-dissipating fins through the first heat sinks and the second heat sinks. Thereby, the integrated circuit package system according to the invention has high heat dissipation performance.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. An integrated circuit package system, comprising:
a substrate, having an upper surface and a lower surface;
a plurality of via hole plugs, being formed on the substrate and penetrating from the upper surface to the lower surface of the substrate;
a plurality of leads, formed on the lower surface of the substrate, each lead corresponding to one of the via hole plugs and being bonded to the corresponding via hole plug;
N semiconductor devices, N being a natural number, each semiconductor device being via a respective bottom surface attached on the upper surface of the substrate, each semiconductor device comprising a plurality of bonding pads formed on a respective first top surface of said one semiconductor device;
a plurality of metal wires, each metal wire corresponding to one of the via hole plugs and one of the bonding pads, each metal wire being bonded to the corresponding via hole plug and the corresponding bonding pad;
N first thermal interface material layers, each first thermal interface material layer corresponding to one of the N semiconductor devices and being coated on the first top surface of the corresponding semiconductor device;
N first metal layers, each first metal layer corresponding to one of the N first thermal interface material layers and being formed on the corresponding first thermal interface material layer;
N first heat sinks, each first heat sink corresponding to one of the N first metal layers and being bonded onto the corresponding first metal layer;
N second metal layers, each second metal layer corresponding to one of the N first heat sinks and being formed on the corresponding first heat sink;
an encapsulating body, formed of an encapsulating material to cover the substrate, the N semiconductor devices, the metal wires, the N first thermal interface material layers, the N first metal layers and the N first heat sinks such that the plurality of leads and the N second metal layers are exposed;
N second thermal interface material layers, each second thermal interface material layer corresponding to one of the N second metal layers and being coated on the corresponding second metal layer;
a second heat sink, being mounted on a second top surface of the encapsulating body and being bonded to the N second thermal interface material layers; and
a plurality of heat-dissipating fins, protruding upward from the second heat sink.

2. The integrated circuit package system of claim 1, wherein the N semiconductor devices comprise a semiconductor chip or a semiconductor die.

3. An integrated circuit package system, comprising:
a lead frame, comprising a land and a plurality of leads;
N semiconductor devices, N being a natural number, each semiconductor device being via a respective bottom surface attached on the land, each semiconductor device comprising a plurality of bonding pads formed on a respective first top surface of said one semiconductor device;
a plurality of metal wires, each metal wire corresponding to one of the leads and one of the bonding pads, each metal wire being bonded to the corresponding lead and the corresponding bonding pad;
N first thermal interface material layers, each first thermal interface material layer corresponding to one of the N semiconductor devices and being coated on the first top surface of the corresponding semiconductor device;
N first metal layers, each first metal layer corresponding to one of the N first thermal interface material layers and being formed on the corresponding first thermal interface material layer;
N first heat sinks, each first heat sink corresponding to one of the N first metal layers and being bonded onto the corresponding first metal layer;
N second metal layers, each second metal layer corresponding to one of the N first heat sinks and being formed on the corresponding first heat sink;
an encapsulating body, formed of an encapsulating material to cover the lead frame, the N semiconductor devices, the metal wires, the N first thermal interface material layers, the N first metal layers and the N first heat sinks such that the plurality of leads and the N second metal layers are exposed;
N second thermal interface material layers, each second thermal interface material layer corresponding to one of the N second metal layers and being coated on the corresponding second metal layer;
a second heat sink, being mounted on a second top surface of the encapsulating body and being bonded to the N second thermal interface material layers; and
a plurality of heat-dissipating fins, protruding upward from the second heat sink.

4. The integrated circuit package system of claim 3, wherein the N semiconductor devices comprise a semiconductor chip or a semiconductor die.

5. An integrated circuit package system, comprising:
a substrate, having an upper surface and a lower surface;
a plurality of via hole plugs, being formed on the substrate and penetrating from the upper surface to the lower surface of the substrate;
a plurality of leads, formed on the lower surface of the substrate, each lead corresponding to one of the via hole plugs and being bonded to the corresponding via hole plug;
N semiconductor devices, N being a natural number, each semiconductor device having a respective first top surface and a respective bottom surface and comprising a plurality of bonding pads formed on the bottom surface of said one semiconductor device;
a plurality of bumps, each bump corresponding to one of the via hole plugs and one of the bonding pads, each bump being bonded to the corresponding via hole plug and the corresponding bonding pad;
N first thermal interface material layers, each first thermal interface material layer corresponding to one of the N semiconductor devices and being coated on the first top surface of the corresponding semiconductor device;
N first metal layers, each first metal layer corresponding to one of the N first thermal interface material layers and being formed on the corresponding first thermal interface material layer;
N first heat sinks, each first heat sink corresponding to one of the N first metal layers and being bonded onto the corresponding first metal layer;
N second metal layers, each second metal layer corresponding to one of the N first heat sinks and being formed on the corresponding first heat sink;
an encapsulating body, formed of an encapsulating material to cover the substrate, the N semiconductor devices, the bumps, the N first thermal interface material layers, the N first metal layers and the N first heat sinks such that the plurality of leads and the N second metal layers are exposed;
N second thermal interface material layers, each second thermal interface material layer corresponding to one of the N second metal layers and being coated on the corresponding second metal layer;
a second heat sink, being mounted on a second top surface of the encapsulating body and being bonded to the N second thermal interface material layers; and
a plurality of heat-dissipating fins, protruding upward from the second heat sink.

6. The integrated circuit package system of claim 5, wherein the N semiconductor devices comprise a semiconductor chip or a semiconductor die.

7. An integrated circuit package system, comprising:
a substrate, having an upper surface and a lower surface;
a plurality of via hole plugs, being formed on the substrate and penetrating from the upper surface to the lower surface of the substrate;
a plurality of leads, formed on the lower surface of the substrate, each lead corresponding to one of the via hole plugs and being bonded to the corresponding via hole plug;
N semiconductor devices, N being a natural number, each semiconductor device having a respective first top surface and a respective bottom surface and comprising a plurality of bonding pads formed on the bottom surface of said one semiconductor device, the N first top surfaces of the N semiconductor devices being coplanar;
a plurality of bumps, each bump corresponding to one of the via hole plugs and one of the bonding pads, each bump being bonded to the corresponding via hole plug and the corresponding bonding pad;
N first thermal interface material layers, each first thermal interface material layer corresponding to one of the N semiconductor devices and being coated on the first top surface of the corresponding semiconductor device;
N first metal layers, each first metal layer corresponding to one of the N first thermal interface material layers and being formed on the corresponding first thermal interface material layer;
a first heat sink, bonded onto the N first metal layers;
a second metal layer, formed on the first heat sink;
an encapsulating body, formed of an encapsulating material to cover the substrate, the N semiconductor devices, the bumps, the N first thermal interface material layers, the N first metal layers and the first heat sink such that the plurality of leads and the second metal layer are exposed;
a second thermal interface material layer, coated on the second metal layer;
a second heat sink, being mounted on a second top surface of the encapsulating body and being bonded to the second thermal interface material layer; and
a plurality of heat-dissipating fins, protruding upward from the second heat sink.

8. The integrated circuit package system of claim 7, wherein the N semiconductor devices comprise a semiconductor chip or a semiconductor die.
